(19) United States
(12) Patent Application Publication
(10) Pub. No.: US 2021/0298193 A1
(43) Pub. Date: Sep. 23, 2021

(54) SERVER DEVICE

(71) Applicants: INVENTEC (PUDONG) TECHNOLOGY CORPORATION, Shanghai (CN); INVENTEC CORPORATION, Taipei City (TW)

(72) Inventors: Ping-Wei PENG, Taipei City (TW); Wen-Long HUANG, Shanghai City (CN); Xing LIU, Shanghai City (CN); Liguo ZHOU, Shanghai City (CN)

(73) Assignees: INVENTEC (PUDONG) TECHNOLOGY CORPORATION, Shanghai (CN); INVENTEC CORPORATION, Taipei City (TW)

(21) Appl. No.: 16/901,997

(22) Filed: Jun. 15, 2020

(30) Foreign Application Priority Data
Mar. 19, 2020 (CN) 202010197017.6

(51) Int. Cl. H05K 7/14; G11B 33/12; G11B 33/04; G06F 1/18

(52) U.S. Cl. CPC H05K 7/1488; G06F 1/187; G11B 33/0461; G11B 33/128

(57) ABSTRACT

A server device comprising a chassis, a first hard disk drive frame and a second hard disk drive frame. The first hard disk drive frame is fixed on the chassis. The first hard disk drive frame has at least one first opening exposed to the outside. The second hard disk drive frame is pivotally disposed on the chassis and movable between an in-use position and an inclined position. The second hard disk drive frame has at least one second opening. When the second hard disk drive frame is in the in-use position, the at least one second opening of the second hard disk drive frame is covered by the first hard disk drive frame. When the second hard disk drive frame is in the inclined position, the at least one second opening of the second hard disk drive frame is exposed to the outside.

### CROSS-REFERENCE TO RELATED APPLICATIONS

This non-provisional application claims priority under 35 U.S.C. § 119(a) on Patent Application No(s). 202010197017.6 filed in China, on Mar. 19th, 2020, the entire contents of which are hereby incorporated by reference.

### BACKGROUND OF THE INVENTION

### Technical Field of the Invention

The invention relates to a server device, more particularly to a server device including a pivotable disk drive frame.

### Description of the Related Art

Nowadays, the information technology is under rapid development and personal computers, such as desktop or laptop computers, are indispensable for corporations and individuals when handling various tasks. As communication technology becomes highly developed, the regional business transaction being replaced by transnational electronic commerce has become a trend, and the transnational electronic commerce involves massive data computation that typical personal computers are unable to deal with. Therefore, the data center employs various forms of server systems, such as rack server system, blade server system, and tower server system, to provide e-commerce services for users.

Take a typical rack server as an example, a rack server has a cabinet and a plurality of server hosts accommodated in the cabinet, where the server hosts are arranged in a compact manner to make the best use of the internal space of the cabinet and to achieve the purpose of convenient management. And the server hosts can work collaboratively to obtain an improved computing performance and an enlarged capacity for storage. However, the installations of hard disk drive to the server hosts are troublesome and time-consuming, which remains an issue to be solved for the developers.

### SUMMARY OF THE INVENTION

The invention is to provide a server device enabling a convenient installation of hard disk drives.

One embodiment of this invention provides a server device comprising a chassis, a first hard disk drive frame and a second hard disk drive frame. The first hard disk drive frame is fixed on the chassis. The first hard disk drive frame has at least one first opening exposed to the outside. The second hard disk drive frame is pivotally disposed on the chassis and movable between an in-use position and an inclined position. The second hard disk drive frame has at least one second opening. When the second hard disk drive frame is in the in-use position, the at least one second opening of the second hard disk drive frame is covered by the first hard disk drive frame. When the second hard disk drive frame is in the inclined position, the at least one second opening of the second hard disk drive frame is exposed to the outside.

According to the server device discussed in the aforementioned embodiments, the second hard disk drive frame or the third hard disk drive frame is pivotally disposed on the chassis, and thus the second hard disk drive frame or the third hard disk drive frame can be pivoted relative to the chassis to facilitate the installation or removal of the hard disk drive.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a server device according to a first embodiment of the disclosure;

FIG. 2 is a partially enlarged exploded view of the server device in FIG. 1;

FIG. 3 is a partially enlarged cross-sectional view of the server device in FIG. 1; and

FIG. 4 to FIG. 9 illustrate the installation of a second hard disk drive frame of the server device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

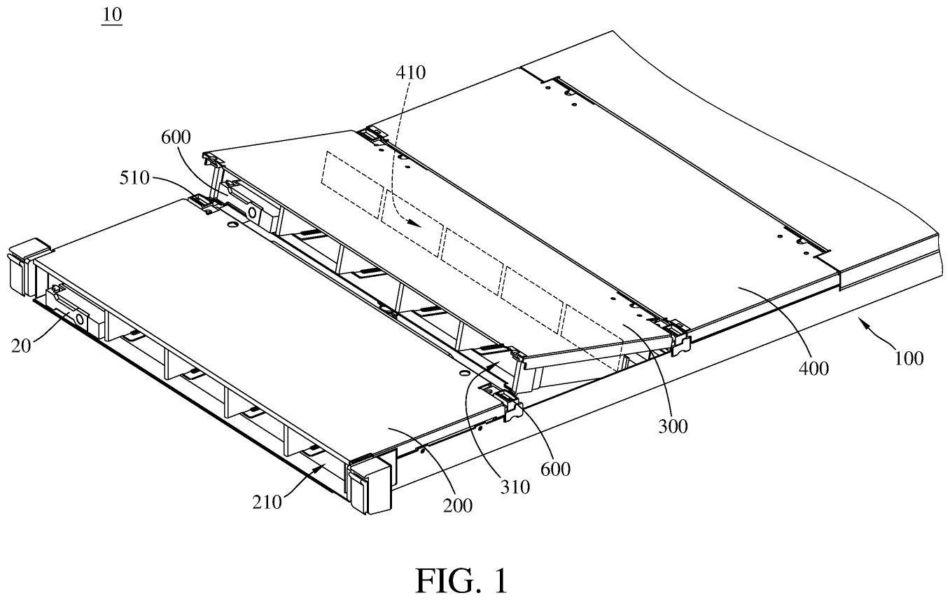

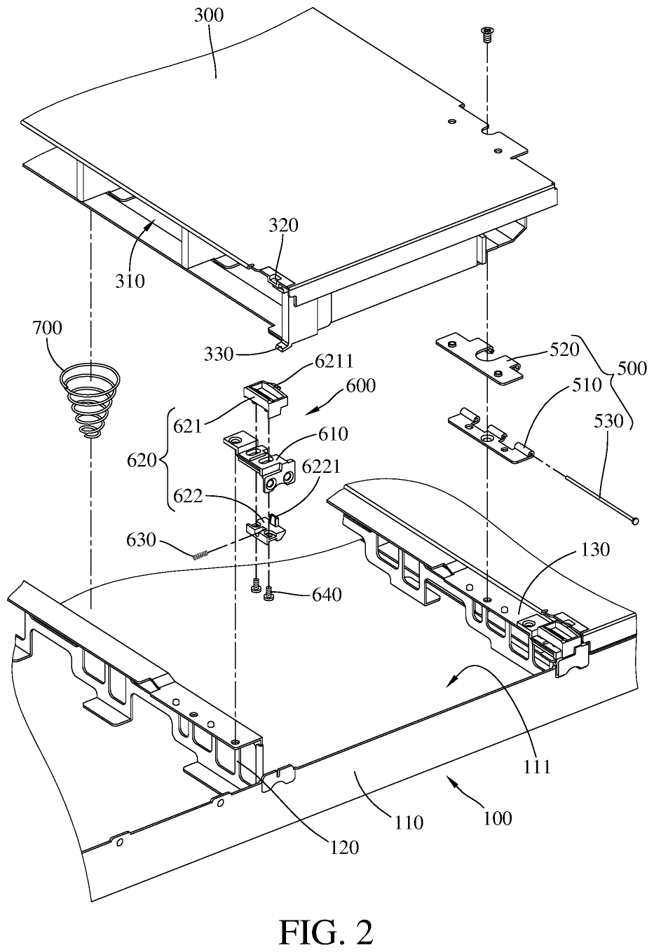

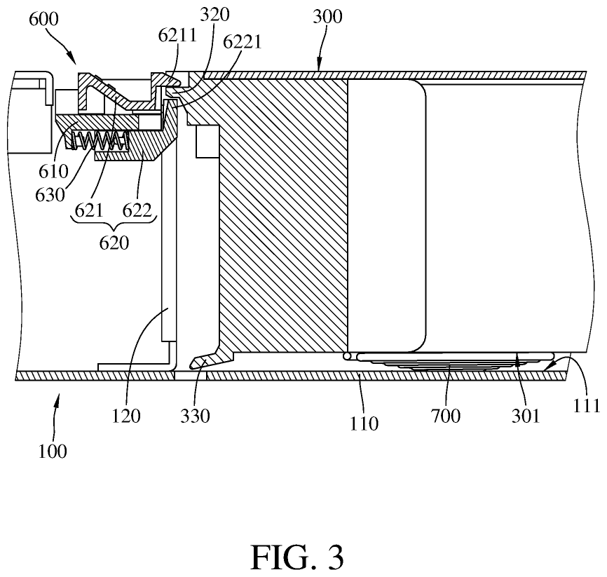

Please refer to FIG. 1 to FIG. 3. FIG. 1 is a perspective view of a server device according to a first embodiment of the disclosure. FIG. 2 is a partially enlarged exploded view of the server device in FIG. 1. FIG. 3 is a partially enlarged cross-sectional view of the server device in FIG. 1.

This embodiment provides a server device 10 including a chassis 100, a first hard disk drive frame (HDD frame) 200, and a second hard disk drive frame 300. In this embodiment, the server device 10 may further include a third hard disk drive frame 400. The chassis 100 includes a carrier part 110, a first partition part 120, and a second partition part 130. The carrier part 110 has a bearing surface 111 configured to bear or support object, such as a server host or other required electric and non-electric components, but the invention is not limited thereto. The first partition part 120 and the second partition part 130 stand on the bearing surface 111 of the carrier part 110 and are spaced apart from each other.

The first hard disk drive frame 200 is fixed to the chassis 100 and is located on a side of the first partition part 120 that is located away from the second partition part 130. The first hard disk drive frame 200 has a plurality of first openings 210 exposed to the outside. As shown, a hard disk drive 20 can be installed into the first hard disk drive frame 200 or removed from the first hard disk drive frame 200 via one of the first openings 210.

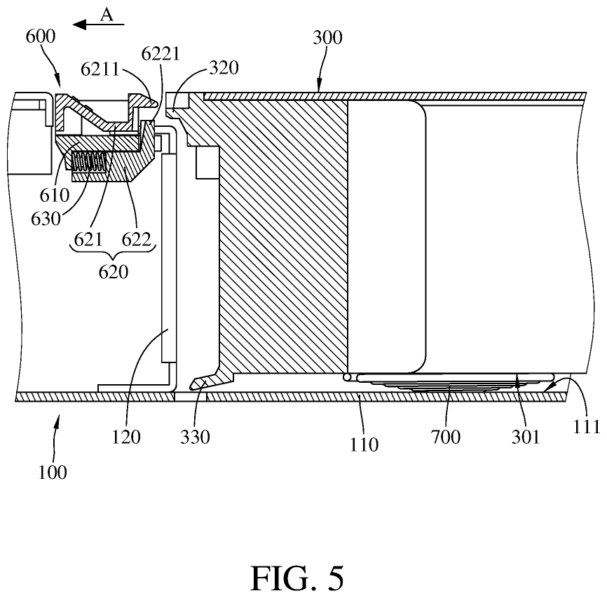

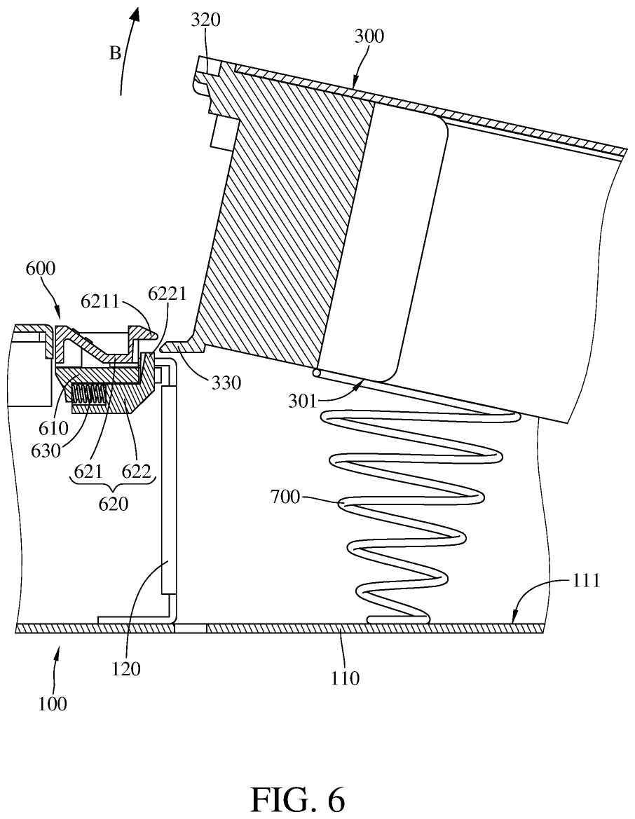

The second hard disk drive frame 300 is located between the first partition part 120 and the second partition part 130, and the second hard disk drive frame 300 is pivotally connected to the chassis 100 and therefore can be switched between an in-use position (as shown in FIG. 3) and an inclined position (as shown in FIGS. 5-6). The second hard disk drive frame 300 has a plurality of second openings 310. When the second hard disk drive frame 300 is in the in-use position, the second openings 310 of the second hard disk drive frame 300 are covered by the first hard disk drive frame 200. When the second hard disk drive frame 300 is in the inclined position, the second openings 310 of the second hard disk drive frame 300 are exposed to the outside, allowing the disk drive 20 to be installed into or removed from the second hard disk drive frame 300 via one of the second openings 310.

The third hard disk drive frame 400 is located on a side of the second partition part 130 that is located away from the first partition part 120, and the third hard disk drive frame 400 is pivotally connected to the chassis 100 and therefore can be switched between an in-use position and an inclined position. The third hard disk drive frame 400 has a plurality of third openings 410. When the third hard disk drive frame 400 is in the in-use position, the third openings 410 of the third hard disk drive frame 400 are covered by the second hard disk drive frame 300. When the third hard disk drive frame 400 is in the inclined position, the third openings 410 of the third hard disk drive frame 400 are exposed to the outside, allowing the disk drive 20 to be installed into or removed from the third hard disk drive frame 400 via one of the third openings 410.

In this embodiment, the second hard disk drive frame 300 and the third hard disk drive frame 400 are pivotally connected to the chassis 100 in a similar manner, and thus only the detail descriptions of the second hard disk drive frame 300 are given below.

In this embodiment, the server device 10 may further include two pivotable assemblies 500 and two releasing assemblies 600. In detail, each pivotable assembly 500 includes a first mount part 510, a second mount part 520, and a shaft 530. The shaft 530 is disposed through the first mount part 510 and the second mount part 520. The first mount part 510 is fixed to the second partition part 130 of the chassis 100. The second mount part 520 is fixed to the second hard disk drive frame 300. The first mount part 510 has a first engagement part 511. The second mount part 520 has a second engagement part 521. One of the first engagement part 511 and the second engagement part 521 is a hole or slot, and the other is a protrusion or block that can be engaged with and movable in the hole. When the first mount part 510 is pivoted relative to the second mount part 520, the cooperation of the first engagement part 511 and the second engagement part 521 limit the angle of rotation between the first mount part 510 and the second mount part 520.

In this embodiment, the server device 10 includes two pivotable assemblies 500 respectively located on two opposite sides of the second hard disk drive frame 300, but the disclosure is not limited thereto. In other embodiments, the server device may only include one pivotable assembly located at the center of the second hard disk drive frame.

The second hard disk drive frame 300 may further have two engagement protrusions 320 and two push protrusions 330. The engagement protrusions 320 and the push protrusions 330 are corresponding to the releasing assemblies 600. In detail, each releasing assembly 600 includes a mount 610, a releasing part 620, and a restoring component 630. The mount 610 is disposed on the first partition part 120 of the chassis 100. The releasing part 620 includes a first piece 621 and a second piece 622. The first piece 621 and the second piece 622 are assembled together via, for example, at least one fastener 640, where each fastener 640 is, for example, slidably disposed in a slot (not numbered) of the mount 610 so that the releasing part 620 can be slidably disposed on the mount 610. The first part 621 of the releasing part 620 has a latching portion 6211 movable relative to the mount 610 and therefore can be switched between an engagement position and a released position. As shown in FIG. 3, the releasing part 620 is in the engagement position, the engagement protrusion 320 of the second hard disk drive frame 300 is stopped from moving by the latching portion 6211, at this moment, the second hard disk drive frame 300 is maintained in the in-use position. As shown in FIG. 5, the releasing part 620 is switched to the released position, the latching portion 6211 of the releasing part 620 is moved away from the engagement protrusion 320 so as to allow the second hard disk drive frame 300 to move to the inclined position. Two opposite ends of the restoring component 630 respectively press against the mount 610 and the releasing part 620 in order to constantly force the releasing part 620 to move towards the engagement position.

The second piece 622 of the releasing part 620 has a supporting portion 6221 that is located closer to a bearing surface 111 of the chassis 100 than the latching portion 6211. The protrusions 330 are located closer to the bearing surface 111 of the chassis 100 than the engagement protrusions 320. When the second hard disk drive frame 300 is in the inclined position and the releasing part 620 is in the engagement position, at least one of the protrusions 330 of the second hard disk drive frame 300 is located between the supporting portion 6221 of the releasing part 620 and the latching portion 6211, such that the second hard disk drive frame 300 can be maintained in the inclined position.

In this embodiment, the quantities of the releasing assemblies 600, the engagement protrusions 320 and the protrusions 330 are two, the two releasing assemblies 600 are respectively located on two opposite sides of the first partition part 120, and the two engagement protrusions 320 and the two protrusions 330 are respectively located on two opposite sides of the second hard disk drive frame 300, but the disclosure is not limited thereto. In other embodiments, the server device may only include one releasing assembly that is located at the center of the first partition part.

Additionally, the second hard disk drive frame 300 has a bottom surface 301. When the second hard disk drive frame 300 is in the in-use position, the bottom surface 301 of the second hard disk drive frame 300 faces toward the bearing surface 111 of the chassis 100.

In this embodiment, the server device 10 may further include an elastic component 700. Two opposite ends of the elastic component 700 respectively press against the bearing surface 111 of the chassis 100 and the bottom surface 301 of the second hard disk drive frame 300 so as to constantly force the second hard disk drive frame 300 to move towards the inclined position.

In this embodiment, the elastic component 700 is, for example, a conical coil spring, but the disclosure is not limited thereto. In other embodiments, the elastic component may be a torsion spring.

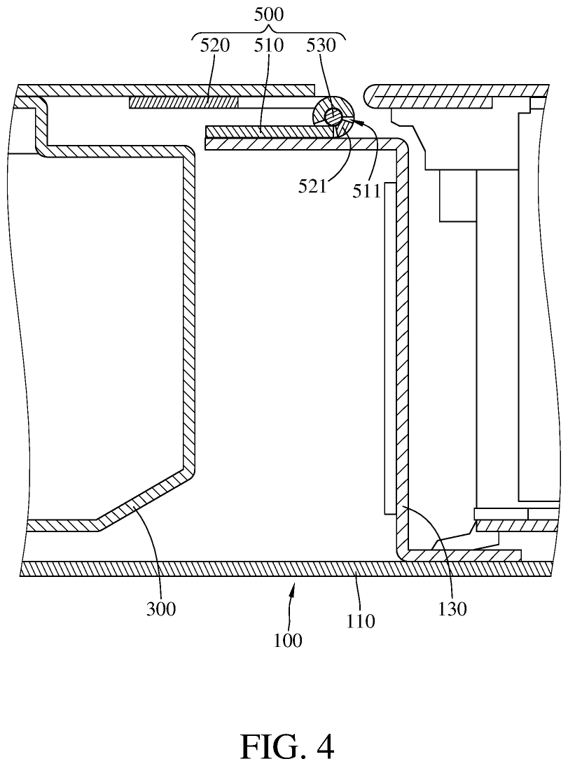

Please refer to FIG. 3 to FIG. 9, where FIGS. 4-9 illustrate the installation of the second hard disk drive frame 300. Firstly, as shown in FIG. 3, the releasing part 620 is in the engagement position and the latching portion 6211 of the releasing part 620 stops the engagement protrusion 320 of the second hard disk drive frame 300 from moving, such that the second hard disk drive frame 300 is maintain in the in-use position.

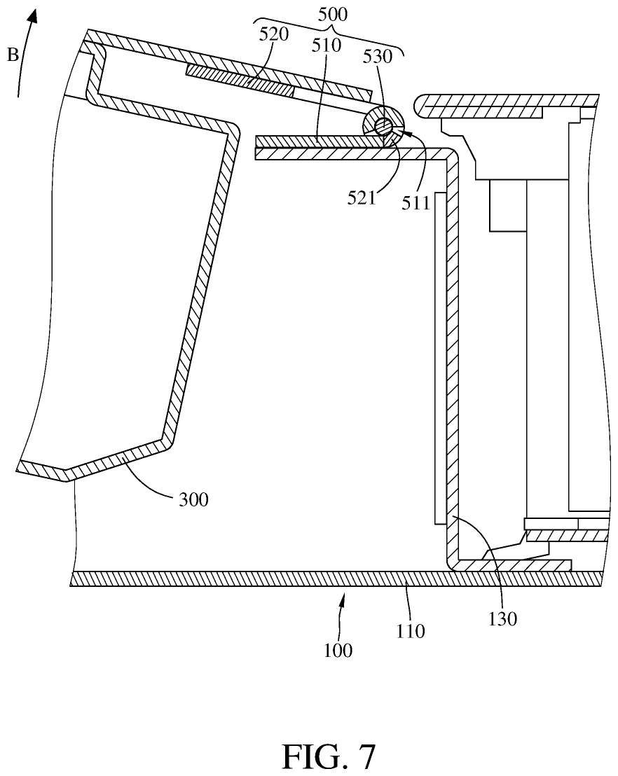

As shown in FIG. 5, the releasing part 620 is switched to the released position along direction A. As shown in FIG. 6, the latching portion 6211 of the releasing part 620 is moved away from the engagement protrusion 320 of the second hard disk drive frame 300 so that the elastic component 700 is released and can push the second hard disk drive frame 300 to move towards the inclined position along direction B. As shown in FIG. 4 and FIG. 7, the second engagement part 521 is moved along the first engagement part 511 and is stopped by one side of the first engagement part 511, thereby stopping the second hard disk drive frame 300 in the inclined position.

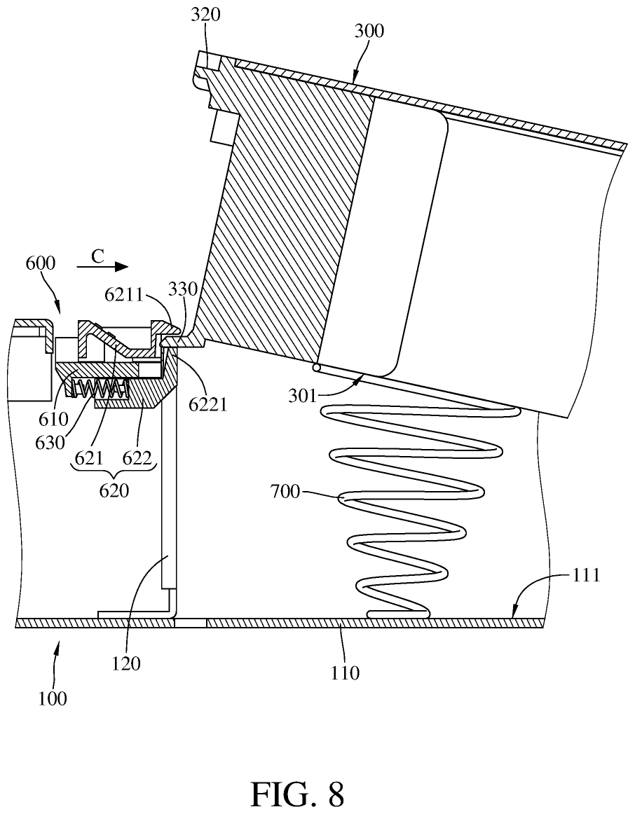

As shown in FIG. 8, the releasing part 620 is released so that the restoring component 630 can return it to the engagement position along direction C. As the releasing part 620 reaches the engagement position, the supporting portion 6221 is able to support the push protrusion 330 of the second hard disk drive frame 300 so as to maintain the second hard disk drive frame 300 in the inclined position, thereby facilitating the installation or removal of the hard disk drive 20.

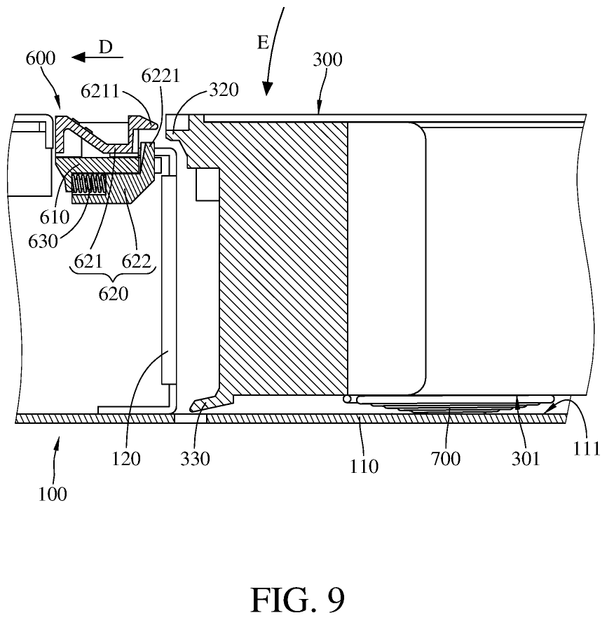

As shown in FIG. 9, the releasing part 620 is moved to the released position along direction D. During this process, the supporting portion 6221 of the releasing part 620 is moved away from the push protrusion 330 of the second hard disk drive frame 300, by doing so, the second hard disk drive frame 300 is allowed to be pressed downwards to the in-use position along direction E.

In this embodiment, the server device 10 includes more than one hard disk drive frame, but the disclosure is not limited thereto. In other embodiments, the server device may only include the first hard disk drive frame and the second hard disk drive frame or may only include the first hard disk drive frame.

According to the server device discussed in the aforementioned embodiments, the second hard disk drive frame or the third hard disk drive frame is pivotally disposed on the chassis, and thus the second hard disk drive frame or the third hard disk drive frame can be pivoted relative to the chassis to facilitate the installation or removal of the hard disk drive.

Further, since one of the first engagement part and the second engagement part is a hole or slot, and the other is a protrusion or block that can be engaged with and movable in the hole, the angle of rotation between the first mount part and the second mount part is restricted. In this way, with the help of the first engagement part and the second engagement part, the elastic component can constantly force the second hard disk drive frame or the third hard disk drive frame to move towards the inclined position in a fast and convenient manner.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A server device, comprising:
a chassis;
a first hard disk drive frame, fixed on the chassis, the first hard disk drive frame having at least one first opening exposed to the outside; and
a second hard disk drive frame, pivotally disposed on the chassis and movable between an in-use position and an inclined position, the second hard disk drive frame having at least one second opening;
wherein when the second hard disk drive frame is in the in-use position, the at least one second opening of the second hard disk drive frame is covered by the first hard disk drive frame; when the second hard disk drive frame is in the inclined position, the at least one second opening of the second hard disk drive frame is exposed to the outside.

2. The server device according to claim 1, further comprising a pivotable assembly, wherein the pivotable assembly comprises a first mount part, a second mount part and a shaft, the shaft is disposed through the first mount part and the second mount part, the first mount part is fixed to the chassis, the second mount part is fixed to the second hard disk drive frame, the first mount part has a first engagement part, the second mount part has a second engagement part, when the first mount part is pivoted relative to the second mount part, the cooperation of the first engagement part and the second engagement part limit the angle of rotation between the first mount part and the second mount part.

3. The server device according to claim 2, wherein one of the first engagement part and the second engagement part is a hole or slot, and another one of the first engagement part and the second engagement part is a protrusion or block that can be engaged with and movable in the one of the first engagement part and the second engagement part.

4. The server device according to claim 2, further comprising an elastic component, wherein the chassis has a bearing surface, the second hard disk drive frame has a bottom surface, the bottom surface faces toward the bearing surface of the chassis, two opposite ends of the elastic component respectively press against the bearing surface of the chassis and the bottom surface of the second hard disk drive frame, and the elastic component constantly forces the second hard disk drive frame to move towards the inclined position.

5. The server device according to claim 4, wherein the elastic component is a conical coil spring.

6. The server device according to claim 4, further comprising at least one releasing assembly, wherein the second hard disk drive frame further has at least one engagement protrusion, the at least one releasing assembly comprises a mount, a releasing part and a restoring component, the mount is disposed on the chassis, the releasing part has a latching portion that is movable relative to the mount between an engagement position and a released position, when the releasing part is in the engagement position the at least one engagement protrusion of the second hard disk drive frame is stopped from moving by the latching portion so that the second hard disk drive frame is maintained in the in-use position, when the releasing part is in the released position, the latching portion of the releasing part is moved away from the at least one engagement protrusion so as to allow the second hard disk drive frame to move to the inclined position, two opposite ends of the restoring component respectively press against to the mount and the releasing part so as to constantly force the releasing part to move towards the engagement position.

7. The server device according to claim 6, wherein quantities of the at least one releasing assembly and the at least one engagement protrusion are two, the two releasing assemblies are respectively located on two opposite sides of the chassis, and the two engagement protrusions are respectively located on two opposite sides of the second hard disk drive frame.

8. The server device according to claim 6, wherein the handle further has a supporting portion that is located closer to the bearing surface of the chassis than the latching portion, the second hard disk drive frame further has at least one protrusion that is located closer to the bearing surface of the chassis than the at least one engagement protrusion, when the second hard disk drive frame is in the inclined position and the releasing part is in the engagement position, the at least one protrusion of the second hard disk drive frame is located between the latching portion and the supporting portion of the releasing part so that the second hard disk drive frame is maintained in the inclined position.

9. The server device according to claim 8, wherein quantities of the at least one releasing assembly and the at least one protrusion are two, the two releasing assemblies are respectively located on two opposite sides of the chassis, and the two protrusions are respectively located on two opposite sides of the second hard disk drive frame.

10. The server device according to claim 1, further comprising a third hard disk drive frame that is pivotally disposed to the chassis and movable between an in-use position and a inclined position, wherein the third hard disk drive frame has at least one third opening, when the third hard disk drive frame is in the in-use position, the at least one third opening of the third hard disk drive frame is covered by the second hard disk drive frame, when the third hard disk drive frame is in the inclined position, the at least one third opening of the third hard disk drive frame is exposed to the outside.
